(19) United States
(12) Patent Application Publication
(10) Pub. No.: US 2009/0058472 A1
(43) Pub. Date: Mar. 5, 2009

(54) VOLTAGE COMPARATOR CIRCUIT

(75) Inventors: Chuan-Tsai Hou, Tu-Cheng (TW); Yi-Lan Liao, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/947,777

(22) Filed: Nov. 30, 2007

(30) Foreign Application Priority Data
Aug. 31, 2007 (CN) 200710201554.8

(51) Int. Cl. H03K 5/24

(52) U.S. Cl. 327/77

(57) ABSTRACT

A voltage comparator circuit includes a voltage input terminal, a first resistor, a second resistor, a first transistor, a second transistor, and a voltage output terminal connected to the collector of the second transistor. The voltage input terminal is connected to ground via the first and second resistors in turn. A node between the first and second resistors is connected to the base of the first transistor. The emitter of the first transistor is grounded. The collector of the first transistor is connected to a direct current (DC) power supply and the base of the second transistor. The emitter of the second transistor is connected to the DC power supply.

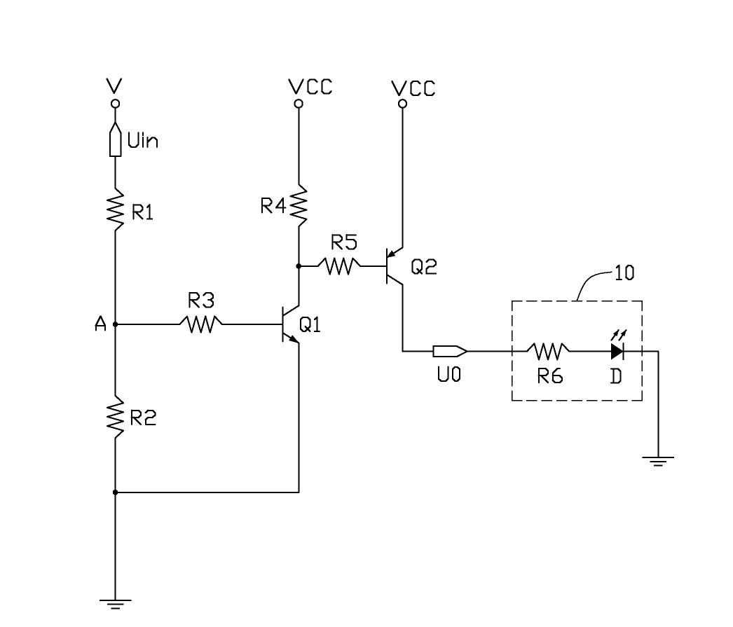

### BACKGROUND

1. Field of the Invention

The present invention relates to voltage comparator circuits, and particularly to a simple voltage comparator circuit which can reduce costs and be easily maintained.

2. Description of Related Art

Nowadays, conventional voltage comparator chips, such as the LM339 voltage comparator chip, are widely applied in many electronic devices. A conventional voltage comparator chip includes a non-inverting input terminal configured to connect to a direct current (DC) power supply, an inverting input terminal configured to connect to a reference voltage, and an output terminal. If the voltage of the DC power supply is greater than the voltage of the reference voltage, the output terminal of the voltage comparator transmits a high level voltage. Contrarily, if the voltage of the DC power supply is less than the voltage of the reference voltage, the output terminal of the voltage comparator transmits a low level voltage.

However, these voltage comparator chips are generally expensive and difficult to maintain, though they have many useful functions. If an electronic device just needs just one basic function of a voltage comparator chip, other functions of the voltage comparator chip will be not used, which is a waste of money.

What is needed is to provide a simple voltage comparator circuit which can reduce costs and be easily maintained.

### SUMMARY

An embodiment of a voltage comparator circuit includes a voltage input terminal, a first resistor, a second resistor, a first transistor, a second transistor, and a voltage output terminal connected to the collector of the second transistor. The voltage input terminal is connected to ground via the first and second resistors in turn. A node between the first and second resistors is connected to the base of the first transistor. The emitter of the first transistor is grounded. The collector of the first transistor is connected to a direct current (DC) power supply and the base of the second transistor. The emitter of the second transistor is connected to the DC power supply.

Other advantages and novel features of the present invention will become more apparent from the following detailed description of an embodiment when taken in conjunction with the accompanying drawing, in which:

### BRIEF DESCRIPTION OF THE DRAWING

The drawing is a circuit diagram of a voltage comparator circuit in accordance with an embodiment of the present invention.

### DETAILED DESCRIPTION

Referring to the drawing, a voltage comparator circuit in accordance with an embodiment of the present invention includes a voltage input terminal Uin, a first resistor R1, a second resistor R2, a third resistor R3, a fourth resistor R4, a fifth resistor R5, a first transistor Q1, a second transistor Q2, a direct current (DC) power supply VCC, and a voltage output terminal Uo. In this embodiment, the first transistor Q1 is an NPN transistor, and the second transistor Q2 is a PNP transistor.

The voltage input terminal Uin is connected to ground via the first resistor R1 and the second resistor R2 in turn. A node “A” between the first resistor R1 and the second resistor R2 is connected to base of the first transistor Q1 via the third resistor R3. The emitter of the first transistor Q1 is grounded. The collector of the first transistor Q1 is connected to the DC power supply VCC via the fourth resistor R4 and connected to the base of the second transistor Q2 via the fifth resistor R5. The emitter of the second transistor Q2 is connected to the DC power supply VCC. The collector of the second transistor Q2 is connected to the voltage output terminal Uo.

The voltage input terminal Uin is configured to receive a DC power supply V which needs to be compared with a reference voltage. The voltage output terminal Uo is configured to transmit voltage to a load 10. For easily illustrating the present invention, the load 10 includes a light-emitting diode (LED) D and a current-limiting resistor R6. The anode of the LED D is connected to the voltage output terminal Uo via the current-limiting resistor R6. The cathode of the LED D is grounded.

In use, if the voltage at the node A is greater than the reference voltage between the base and the emitter of the first transistor Q1, the first transistor Q1 and the second transistor Q2 are turned on, thereby the voltage output terminal Uo transmits a high level voltage, and the LED D is turned on. Contrarily, if the voltage at the node A is less than the reference voltage between the base and the emitter of the first transistor Q1, the first transistor Q1 and the second transistor Q2 are turned off, thereby the voltage output terminal Uo transmits a low level voltage, and the LED D is turned off. Thus, the voltage comparator circuit performs a basic function of a conventional voltage comparator chip.

The voltage comparator circuit can be used in many kinds of electronic devices by suitably adjusting the resistances of the first resistor R1, the second resistor R2, the third resistor R3, the fourth resistor R4, and the fifth resistor R5. Moreover, the voltage comparator circuit is cheaper than the conventional voltage comparator chip, and can be easily maintained.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A voltage comparator circuit comprising:
a voltage input terminal;
a first resistor;
a second resistor, the voltage input terminal connected to ground via the first and second resistors in turn;
a first transistor, a node between the first and second resistors connected to the base of the first transistor, the emitter of the first transistor connected to ground;
a second transistor, the collector of the first transistor connected to a direct current (DC) power supply and the base of the second transistor, the emitter of the second transistor connected to the DC power supply; and
a voltage output terminal connected to the collector of the second transistor.

2. The voltage comparator circuit as claimed in claim 1, wherein a third resistor is connected between the base of the first transistor and the node between the first and second resistors.

3. The voltage comparator circuit as claimed in claim 1, wherein a fourth resistor is connected between the collector of the first transistor and the DC power supply.

4. The voltage comparator circuit as claimed in claim 1, wherein a fifth resistor is connected between the collector of the first transistor and the base of the second transistor.

5. The voltage comparator circuit as claimed in claim 1, wherein the first transistor is an NPN transistor, and the second transistor is a PNP transistor.
